(19) United States
(12) Patent Application Publication
(10) Pub. No.: US 2020/0127016 A1
(43) Pub. Date: Apr. 23, 2020

(54) ARRAY SUBSTRATE, DISPLAY PANEL, AND DISPLAY

(71) Applicants: CHONGQING HKC OPTOELECTRONICS TECHNOLOGY CO., LTD., Chongqing (CN); HKC CORPORATION LIMITED, Shenzhen, Guangdong (CN)

(72) Inventor: Yanna Yang, Chongqing (CN)

(21) Appl. No.: 16/311,332

(22) PCT Filed: Oct. 23, 2018
(86) PCT No.: PCT/CN2018/111486

§ 371 Date: Dec. 19, 2018

(51) Int. Cl. H01L 27/12; H01L 23/00; G02F 1/1362; G02F 1/1345; G02F 1/1339; G02F 1/1333

(52) U.S. Cl. CPC H01L 27/1244; H01L 27/1248; H01L 23/564; G02F 2201/501; G02F 1/13452; G02F 1/1339; G02F 1/133345; G02F 1/136286

(57) ABSTRACT

An array substrate (100) provided by an embodiment of the present application including a chip-on-film connection line (23). The chip-on-film connection line (23) includes: a first metal layer (231), an insulation layer (232), a second metal layer (233), and a passivation layer (234). A surface of the passivation layer (234) has a hydrophobic layer (2340).

### CROSS-REFERENCE TO RELATED APPLICATIONS

This application is the International Application No. PCT/CN2018/111486 for entry into US national phase with an international filing date of Oct. 23, 2018, designating US, now pending, and claims priority to Chinese Patent Application No. 201811012705.X, filed on Aug. 31, 2018, the content of which is incorporated herein by reference in its entirety.

### BACKGROUND OF THE INVENTION

### Field of the Invention

The present application relates to the technical field of display technologies, and more particularly to an array substrate, a display panel, and a display.

### Description of Related Art

A Liquid Crystal Display (LCD) is a commonly used electronic device and is widely favored by users due to its low power consumption, small size, and light weight. The current liquid crystal display device is mainly a thin film transistor (TFT) liquid crystal display (TFT-LCD).

The liquid crystal display mainly includes a liquid crystal display panel and a backlight module. The liquid crystal display panel is mainly formed by a thin film transistor substrate (TFT substrate), a color filter substrate (CF substrate), and a liquid crystal layer sandwiched between the two substrates. In the process of cell assemblage, a seal is applied around the two substrates, a liquid crystal layer is injected into the seal, and the seal is thereafter cured to obtain a liquid crystal display panel structure.

The thin film transistor substrate (TFT substrate), i.e., the array substrate 100′ is typically formed by a display area 10′ and a non-display area 11′ at a periphery of the display area 10′. The display area 10′ is provided therein with a plurality of the scan lines 113′ and a plurality of data lines 114′, the data lines 114′ and the scan lines 113′ intersect to define a plurality of pixel areas. A timing controller (TCON) 110′, configured to provide a data signal to the data lines 114′ and to provide a scan signal to the scan lines 113′, is arranged within the non-display area 11′, and a plurality of chip on films (COF) 111′ are adopted to transmit the data signal and the scan signal to the display area 10′, as shown in FIG. 1. A Wire on Array (WOA) line 112′ is configured to transmit signals between two COFs 111′. In order to reduce the resistance of the WOA line 112′ to prevent decrease in the scan voltage between the two COFs, two overlapping metal layers are generally adopted to design the wiring, and the edges of the two metal layers are cut to be aligned. As shown in FIG. 3, WOA line 112′ is provided on the substrate 12′ and formed by a first metal layer 1120′ and a second metal layer 1122′, insulation layer 1121′ is arranged between the first metal layer 1120′ and the second metal layer 1122′, and the second metal layer 1122′ is further covered with a passivation layer (PV) 1123′. Because a great height difference exists between edges of overlapping regions of the two metal layers, the passivation layer 1123′ deposited on the second metal layer 1122′ has relatively thin film formation at such region. Moreover, in order to achieve ultraviolet irradiation and curing of the seal arranged at a periphery of the liquid crystal display panel from the side that the array substrate 100′ is located, a portion of the WOA line 112′ that overlaps the seal is required to have a certain transmittance. Therefore, the WOA line 112′ is designed to be a hollow-out form, forming a plurality of holes 115′. As shown in FIG. 2, the passivation layer 1123′ is raised and lowered multiple times among the holes 115′, such that relatively thin film forming areas frequently occurs in the passivation layer 1123′, and the overall film forming quality is lowered. It is easy for the water vapor to penetrate into the second metal layer 1122′ due to environmental changes, and the water vapor entering the array substrate 100′ results in bubbles, so that the WOA line 112′ or even the array substrate 100′ is then seriously corroded, affecting the display quality of the panel.

Based on the above, it is necessary to provide an array substrate structure capable of preventing the water vapor from penetrating into the metal layer of the WOA line.

### BRIEF SUMMARY OF THE INVENTION

It is an object of embodiments of the present application to provide an array substrate, which aims at solving the problem that the WOA lines are apt to be corroded by the water vapor penetration.

In order to solve the technical solutions, technical solutions adopted by embodiments of the present applications are as follows: an array substrate is provided. The array substrate comprises a substrate base layer. A display area and a non-display area are arranged on the substrate base layer. The non-display area comprises a plurality of chip-on-film connection lines arranged on the substrate base layer.

A respective chip-on-film connection line comprises:

a first metal layer, arranged on the substrate base layer;

an insulation layer, arranged on the first metal layer;

a second metal layer, arranged on the insulation layer; and

a passivation layer, arranged on the second metal layer.

A surface of the passivation layer is provided with a hydrophobic layer.

In the array substrate provided by one embodiment of the present application, the chip-on-film connection line of the non-display area comprises: the first metal layer arranged on the substrate base layer, the insulation layer arranged on the first metal layer, the second metal layer arranged on the insulation layer, and the passivation layer arranged on the second metal layer; and the surface of the passivation layer is provided with the hydrophobic layer. The hydrophobic layer is capable of effectively preventing the water vapor from penetrating into the second metal layer arranged beneath the passivation layer, therefore further preventing the chip-on-film connection line of the non-display area from being corroded and preventing further penetration of the water vapor into the display area. In this way, the display effect of the display area of the array substrate is ensured, the qualities of the display panel and the display are ensured, and service lives thereof are improved.

It is another object of one embodiment of the present application to provide a display panel. The display panel comprises an array substrate.

The array substrate comprises a substrate base layer. A display area and a non-display area are arranged on the substrate base layer. The non-display area comprises a plurality of chip-on-film connection lines arranged on the substrate base layer.

A respective chip-on-film connection line comprises:

a first metal layer, arranged on the substrate base layer;

an insulation layer, arranged on the first metal layer;

a second metal layer, arranged on the insulation layer; and

a passivation layer, arranged on the second metal layer.

A surface of the passivation layer is provided with a hydrophobic layer.

The passivation layer comprises a first sub-passivation layer arranged on the second metal layer and a second sub-passivation layer arranged on the first sub-passivation layer. The hydrophobic layer is arranged on a surface of the second sub-passivation layer; and the first sub-passivation layer has a thickness of 200-230 nm, and the second sub-passivation layer has a thickness of smaller than 230 nm.

In the display panel provided by one embodiment of the present application, the chip-on-film connection line of the non-display area of the array substrate comprises: the first metal layer arranged on the substrate base layer, the insulation layer arranged on the first metal layer, the second metal layer arranged on the insulation layer, and the passivation layer arranged on the second metal layer; and the surface of the passivation layer is provided with the hydrophobic layer. The hydrophobic layer is capable of effectively preventing the water vapor from penetrating into the second metal layer arranged beneath the passivation layer, therefore further preventing the chip-on-film connection line of the non-display area from being corroded and preventing further penetration of the water vapor into the display area. Moreover, the passivation layer comprises the first sub-passivation layer and the second sub-passivation layer; the first the thickness of the sub-passivation layer is 200-230 nm, and the thickness of the second sub-passivation layer is smaller than 230 nm, in this way, the thickness of the passivation layer is increased, which further ensures the display effect of the display area of the array substrate, thus ensuring the qualities of the display panel and the display and improving the service lives thereof.

It is still another object of one embodiment of the present application to provide a display. The display comprises a display panel. The display panel comprises an array substrate.

The array substrate comprises a substrate base layer. The display area and a non-display area are arranged on the substrate base layer. The non-display area comprises a plurality of chip-on-film connection lines arranged on the substrate base layer.

A respective chip-on-film connection line comprises:

a first metal layer, arranged on the substrate base layer;

an insulation layer, arranged on the first metal layer;

a second metal layer, arranged on the insulation layer; and

a passivation layer, arranged on the second metal layer.

A surface of the passivation layer is provided with a hydrophobic layer.

In the display provided by one embodiment of the present application, the chip-on-film connection line of the non-display area comprises: the first metal layer arranged on the substrate base layer, the insulation layer arranged on the first metal layer, the second metal layer arranged on the insulation layer, and the passivation layer arranged on the second metal layer; and the surface of the passivation layer is provided with the hydrophobic layer. The hydrophobic layer is capable of effectively preventing the water vapor from penetrating into the second metal layer arranged beneath the passivation layer, therefore further preventing the chip-on-film connection line of the non-display area from being corroded and preventing further penetration of the water vapor into the display area. In this way, the display effect of the display area of the array substrate is ensured, the qualities of the display panel and the display are ensured, and service lives thereof are improved.

### BRIEF DESCRIPTION OF THE DRAWINGS

In order to more clearly illustrate the technical solutions in embodiments of the present application, the drawings used in the description of the embodiments or the existing techniques will be briefly described hereinbelow. Apparently, the drawings in the following description are only some embodiments of the present application. Other drawings may be obtained by those skilled in the art without departing from the scope of the invention.

FIG. 1 is a structural view of an exemplary array substrate;

FIG. 2 is an enlarged view of a structure of a chip-on-film connection line in a broken line frame of FIG. 1;

FIG. 3 is a cross-sectional view of a chip-on-film connection line of FIG. 2 taken from line A-A;

FIG. 4 is a top structural schematic view of an array substrate according to a first embodiment of the present application;

FIG. 5 is a cross-sectional structural schematic view of an array substrate of FIG. 4 taken along line B-B;

FIG. 6 is a cross-sectional structural schematic view of the array substrate according to a second embodiment of the present application;

FIG. 7 is a cross-sectional structural schematic view of an array substrate according to a third embodiment of the present application; and

FIG. 8 is a structural schematic view of a liquid crystal display panel according to a fourth embodiment of the present application.

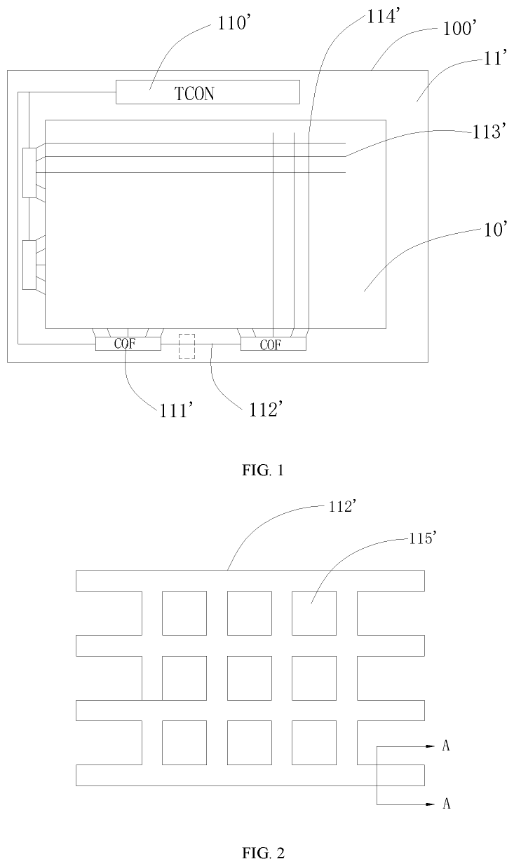

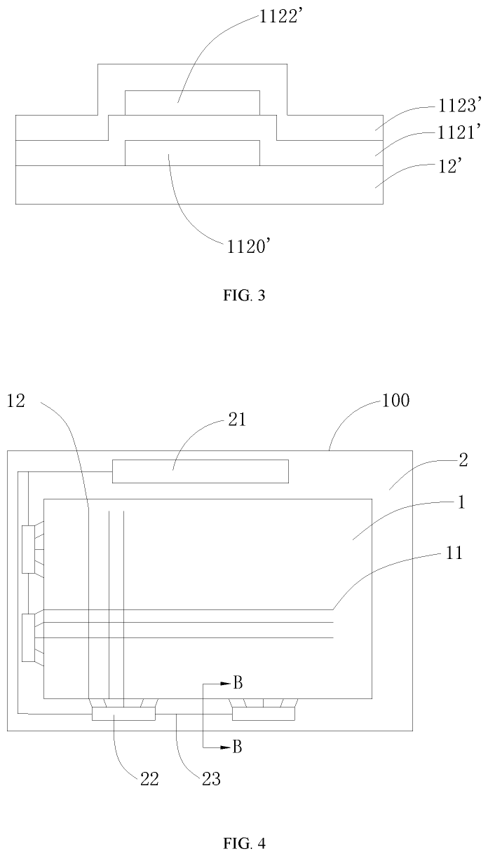

### DETAILED DESCRIPTION OF THE EMBODIMENTS

In order to make the technical problems to be solved, technical solutions, and beneficial effects of the present application more clear, the present application will be further described in detail hereinbelow with reference to the accompanying drawings and embodiments. It should be understood that the specific embodiments described herein are merely intended to explain the application rather than to limit the present application.

It should be noted that when an element is referred to as being “fixed” or “arranged” at/in/on another element, it can be directly at/in/on the other element. When an element is referred to as being “connected” to/with the another element, it can be directly or indirectly connected to/with the other element. Moreover, the terms “first” and “second” are adopted for descriptive purposes only and are not to be construed as indicating or implying a relative importance or implicitly indicating the number of technical features indicated. Thus, features defining “first” and “second” may include one or more of the features either explicitly or implicitly. In the description of the present application, the meaning of “a plurality of or “multiple” is two or more unless otherwise particularly defined.

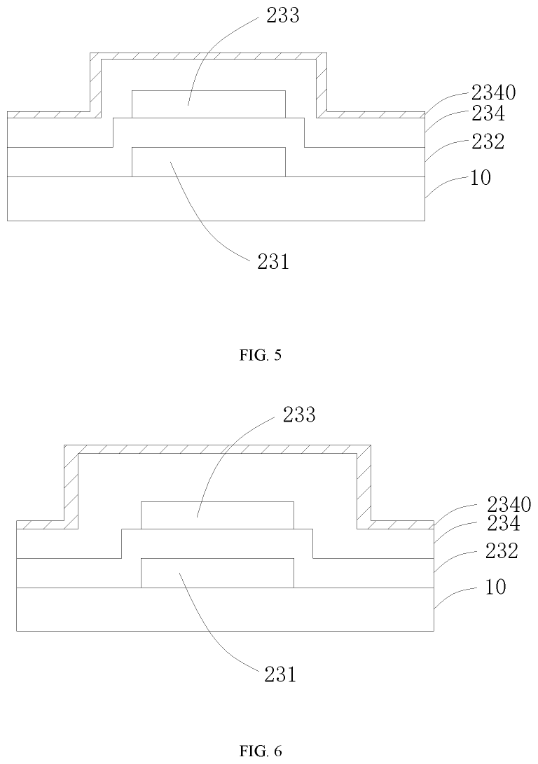

As shown in FIGS. 4-5, an array substrate 100 provided by the present application comprises a substrate base layer 10. On the substrate base layer 10, the array substrate 100 further comprises a display area 1 and a non-display area 2 arranged at a periphery of the display area 1. A plurality of data lines 12 and a plurality of scan lines 11 are arranged within the display area 1. The plurality of data lines 12 are arranged to extend in a column direction and be spaced apart from each other in a row direction. The plurality of scan lines 11 are arranged to extend in the row direction and be spaced apart from each other in the column direction. The plurality of the scan lines 11 and the plurality of the data lines 12 intersect to define a plurality of pixel areas. The non-display area 2 comprises a timing controller 21 configured to provide a data signal to a respective data line 12 and provide a scan signal to a respective scan line 11. Signal transmission between the timing controller 21 and the scan lines 11 and signal transmission between the timing controller 21 and the data lines 12 are achieved by a plurality of chip-on-films 22. The non-display area 2 is provided therein with at least one chip-on-film connection line 23, and the plurality of chip-on-films 22 are connected via the at least one chip-on-film connection line 23.

As shown in FIGS. 5-7, a respective chip-on-film connection line 23 comprises: a first metal layer 231 disposed on the substrate base layer 10, an insulation layer 232 disposed on the first metal layer 231, a second metal layer 233 disposed on the insulation layer 232, and a passivation layer 234 disposed on the second metal layer 233, in which, a surface of the passivation layer 234 has a hydrophobic layer 2340.

In the array substrate 100 provided by the present application, the chip-on-film connection line 23 of the non-display area 2 comprises: the first metal layer 231 and the second metal layer 233 separated by the insulation layer 232, and the passivation layer 234 disposed on the second metal layer 233. By placing the hydrophobic layer 2340 on the surface of the passivation layer 234, the path of water vapor penetration can be blocked. Even the film thickness of the passivation layer 234 is relatively small due to the height difference between edges of the first metal layer 231 and the second metal layer 233 that align with each other, the water vapor can be effectively prevented from penetrating into the second metal layer 233 via the passivation layer 234 at such step difference. In this way, the chip-on-film connection lines 23 and an internal part of the display area 1 of the array substrate 100 are prevented from being subjected to corrosion of the water vapor, and the sealing effect of the array substrate 100 and the display quality of the display area 1 are ensured.

As shown in FIG. 4, the chip-on-film connection line 23 has a width of 20-30 μm. The non-display area 2 is configured in such a way that the array substrate 100 and a color film substrate 200 are adhered by a seal 400 to form a liquid crystal display 60 (which will be described in detail hereinbleow). The seal 400 is arranged above the chip-on-film connection lines 23 and overlaps with at least a part of the chip-on-film connection line 23. In order to irradiate and cure the seal 400 arranged at the non-display area 2 from the side where the array substrate 100 is located, a respective chip-on-film connection line 23 defines a plurality of through holes, configured to allow the ultraviolet irradiation to pass through.

A width of a respective through hole (in a width direction of the chip-on-film connection line 23) is 1-10 μm, and optionally, 1-6 μm. A length of the respective through hole (in a length direction of the chip-on-film connection line 23) is 1-15 μm, and optionally, 1-10 μm.

In a first embodiment of the present application, as shown in FIG. 5, the passivation layer 234 is made from an inorganic material of silicon oxide (SiOₓ) or silicon nitride (SiNₓ), and the passivation layer 234 has a thickness of 200-230 nm. In particular, the passivation layer 234 is treated with fluoride ions to form a hydrophobic layer 2340 on a surface of the passivation layer 234. Specific steps are as follows: ionizing a gas mixture obtained by mixing CF₄ or SF₆ with O₂, performing dry etching on the surface of the passivation layer 234 of the inorganic material by an ionized gas mixture, and forming hydrophobic groups on the surface of the passivation layer 234 to obtain the hydrophobic layer 2340.

For the display area 1, a gate and the scan lines 11 are formed on the substrate base layer 10, a gate insulating layer is formed on the gate and the scan lines, an active layer is formed on the gate insulating layer, a source/drain and the data lines 12 are formed on the active layer, the gate, the active layer, and the source/drain form a thin film transistor (TFT, not shown in the figures), and the passivation layer is formed on the TFT. The passivation layer on the TFT within the display area 1 has a thickness of 200-230 nm, that is, the passivation layer 2340 of the chip-on-film connection line 23 located within the non-display area 2 and the passivation layer on the TFT within the display area 1 have the same thickness, and can be formed by the same chemical vapor deposition process. After deposition, it only requires to perform the hydrophobic treatment of the passivation layer 234 located within the non-display area.

In a second embodiment of the FIG. 6 of the present application, the passivation layer 234 is made from an inorganic material of silicon oxide (SiOₓ) and silicon nitride (SiNₓ), and the passivation layer 234 has a thickness of greater than 230 nm. In particular, the passivation layer 234 is treated with fluoride ions to form a hydrophobic layer 2340 on a surface of the passivation layer 234. Specific steps are as follows: ionizing a gas mixture obtained by mixing CF₄ or SF₆ with O₂, performing dry etching on the surface of the passivation layer 234 of the inorganic material by an ionized gas mixture, and forming hydrophobic groups on the surface of the passivation layer 234 to obtain the hydrophobic layer 2340. Compared with the first embodiment, the passivation layer 234 of this embodiment has greater thickness, which can further improve the film forming quality of the passivation layer 234 at the overlapping edges of the first metal layer 231 and the second metal layer 233, and therefore improves the capability of the passivation layer 234 to block the water vapor.

Optionally, the passivation layer 234 has a thickness of 230-300 nm, or alternatively, 300-400 nm, or alternatively, 400-460 nm.

In the second embodiment, the thickness of the passivation layer 234 in the non-display area 2 is greater than that of the passivation layer on the TFT within the display area 1. In this case, after a passivation layer having a thickness of greater than 230 nm is formed by one time chemical vapor deposition, a portion of the passivation layer on the TFT within the display area can be removed. Thus, not only is the thickness of the passivation layer 234 of the chip-on-film connection line 23 maintained greater than 230 nm, but also the passivation layer on the TFT within the display area 1 is maintained at 200-230 nm.

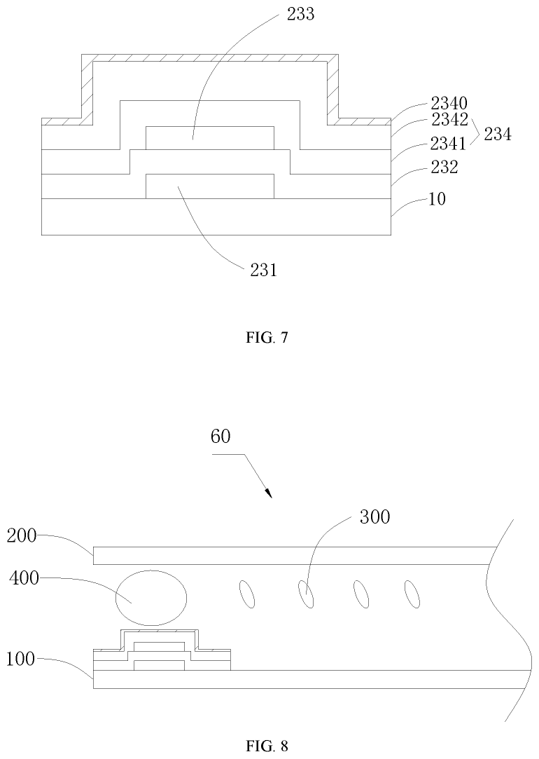

In a third embodiment of the present application, as illustrated in FIG. 7, the passivation layer 234 comprises a first sub-passivation layer 2341 disposed on the second metal layer 233 and a second sub-passivation layer 2234 disposed on the first sub-passivation layer 2341. A hydrophobic layer 2340 is formed on the surface of the second sub-passivation layer 2342. The sum of the thicknesses of the first sub-passivation layer 2341 and the second sub-passivation layer 2342 is greater than 230 nm.

In particular, the first sub-passivation layer 2341 has a thickness of 200-230 nm, and the second sub-passivation layer 2342 has a thickness of smaller than 230 nm, for example, smaller than 70 nm, 70-170 nm, or alternatively, 170-230 nm, and the thickness of the passivation layer 234 is 230-460 nm.

Optionally, the first passivation layer 2341 is made from an inorganic material of silicon oxide (SiOₓ) or silicon nitride (SiNₓ), and the second passivation layer 2342 is made from an organic material, such as an organic photoresist material. The first sub-passivation layer 2341 of the passivation layer 234 is fabricated according to a conventional fabrication process of the array substrate 100, e.g., the first sub-passivation layer 2341 is formed in the same layer as the passivation layer deposited on the TFT within the display area. The second sub-passivation layer 2342 is formed by depositing a layer of organic photoresist material, which is then subjected to exposure, development, and etching so as to remain on the firs sub-passivation layer 2341.

In particular, the second sub-passivation layer 2342 of the organic photoresist material is subjected to the hydrophobic treatment by ionizing a gas mixture obtained by mixing CF₄ or SF₆ with O₂, performing dry etching on the surface of the passivation layer 2342 of the inorganic material by an ionized gas mixture, and forming hydrophobic groups on the surface of the passivation layer 2342 to obtain the hydrophobic layer 2340.

Optionally, both the first sub-passivation layer 2341 and the second sub-passivation layer 2342 are made from inorganic materials of silicon oxide (SiOₓ) or silicon nitride (SiNₓ), the first sub-passivation layer 2341 is formed in the same layer as the passivation layer deposited on the TFT within the display area, which will not be repeated herein. Thereafter, the second sub-passivation layer 2341 is obtained by only performing another chemical vapor deposition on the non-display area 2.

In particular, the first metal layer 231, the insulation layer 232, and the second metal layer 233 of the chip-on-film connection line 23 are formed simultaneously with the scan lines 11 and the data lines 12 within the display area 1, that is, the first metal layer 231 may be formed in the same layer as the gate of the TFT and the scan line 11 within the display area 1, and the insulation layer 232 may be formed in the same layer as the gate insulating layer of the TFT within the display area 1, and the second metal layer 233 may be formed in the same layer as the data lines 12 and the source/drain of the TFT.

The first metal layer 231 does not have to be a metal layer, it may be a single metal layer, such as chromium (Cr), molybdenum (Mo), copper (Cu), titanium (Ti). It may also be stacked layers of the same metal material. It may also be a composite metal layer of different metallic materials, such as a molybdenum/aluminum (Mo/Al) composite layer. The first metal layer 231 has a thickness of 200-800 nm, or alternatively, 200-550 nm.

The second metal layer 233 does not have to be a metal layer, it may be a single metal layer, such as chromium (Cr), molybdenum (Mo), copper (Cu), titanium (Ti). It may also be stacked layers of the same metal material. It may also be a composite metal layer of different metallic materials, such as a molybdenum/aluminum (Mo/Al) composite layer. The second metal layer 233 has a thickness of 200-800 nm, or alternatively, 200-550 nm.

The insulation layer 232 is made from at least one of silicon oxide (SiOₓ) and silicon nitride (SiNₓ) and is deposited on the first metal layer 231 by chemical vapor deposition. The insulation layer 232 has a thickness of 100-300 nm.

As shown in FIG. 8, a fourth embodiment of the present application provides a liquid crystal display panel 60, comprising the array substrate 100 according to the first to third embodiments, and a color film substrate 200 disposed opposite the array substrate 100. A peripheral region of the array substrate 100 is provided with a seal 400, configured to adhere the color film substrate 200 and be disposed above the chip-on-film connection line 23. The chip-on-film connection line 23 has a width of 20-30 μm, and the chip-on-film connection line 23 defines thereon a plurality of through holes for allowing ultraviolet irradiation to pass through. The ultraviolet light is irradiated from the side where the array substrate 100 is located to the seal 400, and the seal 400 is cured to obtain the liquid crystal display panel 60. In the liquid crystal display panel 60 of the present application, the surface of the passivation layer 234 of the chip-on-film connection line 23 within the non-display area 2 of the array substrate 100 has a hydrophobic layer 2340, which is capable of preventing the water vapor from penetrating in via the passivation layer 234 at overlapping edge regions of the two metal layers of the chip-on-film connection line 23, and therefore has better sealing effect and display quality.

The present application also provides a liquid crystal display (not shown), comprising the liquid crystal display panel 60 according to the fourth embodiment as described in the above and a backlight module disposed on the side where the array substrate 100 is located. In the liquid crystal display of the present application, a surface of the passivation layer 234 of the chip-on-film connection line 23 within the non-display area 2 of the array substrate 100 of the liquid crystal panel has a hydrophobic layer 2340, which is capable of preventing the water vapor from penetrating in via the passivation layer 234 at overlapping edge regions of the two metal layers of the chip-on-film connection line 23, and therefore has better sealing effect and display quality.

The above description is only optional embodiments of the present application, and is not intended to limit the present application. Any modifications, equivalent substitutions, and improvements made within the spirit and principles of the present application are included within the protection scope of the present application.

1. An array substrate, comprising a substrate base layer with a display area and a non-display area arranged on the substrate base layer; the non-display area comprising a plurality of chip-on-film connection lines arranged on the substrate base layer; and
a respective chip-on-film connection line comprising:
a first metal layer, arranged on the substrate base layer;
an insulation layer, arranged on the first metal layer;
a second metal layer, arranged on the insulation layer, an edge of the second metal layer is set in alignment with an edge of the second metal layer; and
a passivation layer, arranged on the second metal layer; wherein a surface of the passivation layer is provided with a hydrophobic layer.

2. The array substrate of claim 1, wherein the passivation layer has a thickness of 200-460 nm.

3. The array substrate of claim 2, wherein the thickness of the passivation layer is 200-230 nm.

4. The array substrate of claim 2, wherein the thickness of the passivation layer is 200-230 nm, or alternatively, 300-400 nm, or alternatively, 400-460 nm.

5. The array substrate of claim 2, wherein the passivation layer is made from a material of at least one of silicon oxide and silicon nitride.

6. The array substrate of claim 1, wherein the passivation layer comprises: a first sub-passivation layer disposed on the second metal layer, and a second sub-passivation layer disposed on the first sub-passivation layer; and the hydrophobic layer is arranged on a surface of the second sub-passivation layer.

7. The array substrate of claim 6, wherein the first sub-passivation layer has a thickness of 200-230 nm, and the second sub-passivation layer has a thickness of smaller than 230 nm.

8. The array substrate of claim 6, wherein the thickness of the second sub-passivation layer is smaller than 70 nm, or alternatively, 70-170 nm, or alternatively, 170-230 nm.

9. The array substrate of claim 6, wherein the first passivation layer is made from a material of at least one of silicon oxide and silicon nitride; and the second passivation layer is made from an organic photoresist material.

10. The array substrate of claim 6, wherein the first passivation layer is made from a material of at least one of silicon oxide and silicon nitride; and the second passivation layer is made from a material of at least one of silicon oxide and silicon nitride.

11. The array substrate of claim 1, wherein the respective chip-on-film connection line has a width of 20-30 μm, and the respective chip-on-film connection line defines thereon a plurality of through holes for allowing ultraviolet irradiation to pass through.

12. The array substrate of claim 11, wherein a respective through hole has a width of 1-10 μm and a length of 1-15 μm.

13. The array substrate of claim 1, wherein scan lines and data lines are formed within the display area; and the first metal layer is arranged at the same layer as the scan lines, and the second metal layer is arranged at the same layer as the data lines.

14. The array substrate of claim 1, wherein a thin film transistor is formed within the display area; and the insulation layer of the chip-on-film connection line is arranged at the same layer as a gate insulating layer of the thin film transistor.

15. A display panel, comprising an array substrate;
the array substrate comprising a substrate base layer with a display area and a non-display area arranged on the substrate base layer; the non-display area comprising a plurality of chip-on-film connection lines arranged on the substrate base layer;
a respective chip-on-film connection line comprising:
a first metal layer, arranged on the substrate base layer;
an insulation layer, arranged on the first metal layer;
a second metal layer, arranged on the insulation layer, an edge of the second metal layer is set in alignment with an edge of the second metal layer; and
a passivation layer, arranged on the second metal layer, wherein a surface of the passivation layer is provided with a hydrophobic layer; and
the passivation layer comprising a first sub-passivation layer arranged on the second metal layer and a second sub-passivation layer arranged on the first sub-passivation layer, wherein the hydrophobic layer is arranged on a surface of the second sub-passivation layer; and the first sub-passivation layer has a thickness of 200-230 nm, and the second sub-passivation layer has a thickness of smaller than 230 nm.

16. A display, comprising a display panel; the display panel comprising an array substrate;
the array substrate comprising a substrate base layer with a display area and a non-display area arranged on the substrate base layer; the non-display area comprising a plurality of chip-on-film connection lines arranged on the substrate base layer;
a respective chip-on-film connection line comprising:
a first metal layer, arranged on the substrate base layer;
an insulation layer, arranged on the first metal layer;
a second metal layer, arranged on the insulation layer, an edge of the second metal layer is set in alignment with an edge of the second metal layer; and
a passivation layer, arranged on the second metal layer, wherein a surface of the passivation layer is provided with a hydrophobic layer.
